(19) United States
(12) Patent Application Publication
(10) Pub. No.: US 2024/0282780 A1
(43) Pub. Date: Aug. 22, 2024

(54) ARRAY SUBSTRATE AND DISPLAY PANEL

(71) Applicant: KunShan Go-Visionox Opto-Electronics Co., Ltd, Kunshan (CN)

(72) Inventors: Yu JIN, Kunshan (CN); Lei XU, Kunshan (CN); Weijie GU, Kunshan (CN); Shuilin XIE, Kunshan (CN); Lei LI, Kunshan (CN); Zhiyi ZHOU, Kunshan (CN)

(73) Assignee: KunShan Go-Visionox Opto-Electronics Co., Ltd, Kunshan (CN)

(21) Appl. No.: 18/602,403

(22) Filed: Mar. 12, 2024

Related U.S. Application Data
(63) Continuation of application No. PCT/CN2022/122285, filed on Sep. 28, 2022.

(30) Foreign Application Priority Data
Jun. 28, 2022 (CN) 202210740034.9

(51) Int. Cl. H01L 27/12

(52) U.S. Cl. CPC H01L 27/124

(57) ABSTRACT

An array substrate and a display panel, the array substrate includes an array layer, and a first conductive line and a first electrode that are disposed on the array layer, and the first electrode is electrically connected with the array layer via the first conductive line; a protection member is disposed at an edge of the first electrode, and an orthogonal projection of the protection member on the array layer at least partially overlaps with an orthogonal projection of the first conductive line on the array layer.

### CROSS-REFERENCE TO RELATED APPLICATIONS

This application is a continuation of International Application No. PCT/CN2022/122285, filed on Sep. 28, 2022, which claims priority to Chinese Patent Application No. 202210740034.9, filed to the China National Intellectual Property Administration on Jun. 28, 2022, and entitled “ARRAY SUBSTRATE AND DISPLAY PANEL”. The entire contents of the aforementioned applications are hereby incorporated by reference.

### TECHNICAL FIELD

The application relates to the technical field of display panels, and in particular, to an array substrate and a display panel.

### BACKGROUND

With the development of display technology, the market demand for display panels with high screen-to-body ratio is more and more urgent, and the display panels are developing towards full screen.

In the related art, a display panel includes a light-transmitting region, and an under-screen functional device is integrated on a backlight surface of the display panel in the light-transmitting region, on one hand, light can pass through the display panel in the light-transmitting region and reach the under-screen functional device, which realizes functions of the under-screen functional device; on the other hand, the display panel in the light-transmitting region may also emit light normally, which realizes a display function and ensures that the display panel has a high screen-to-body ratio.

However, an anode in the above light-transmitting region is prone to be over-etched in the preparation process, which affects displaying effect of the display panel.

### SUMMARY

In view of the above problems, embodiments of the present application provide an array substrate and a display panel, which can alleviate a phenomenon of over-etching of an anode in a preparation process, thereby improving displaying effect of the display panel.

In order to achieve the above objects, embodiments of the present application provide the following technical solutions.

A first aspect of the embodiments of the present application provides an array substrate, including:
an array layer; and
a first conductive line and a first electrode that are disposed on the array layer; and
where the first electrode is electrically connected with the array layer via the first conductive line; an edge of the first electrode is provided with a protection member, and an orthogonal projection of the protection member on the array layer at least partially overlaps with an orthogonal projection of the first conductive line on the array layer.

The array substrate provided in the embodiments of the present application includes an array layer, and a first conductive line and a first electrode are disposed on the array layer, and the first electrode is electrically connected with the array layer via the first conductive line, so that the array layer transmits signals to the first electrode via the first conductive line. A protection member is disposed at an edge of the first electrode, and an orthogonal projection of the protection member on the array layer at least partially overlaps with an orthogonal projection of the first conductive line on the array layer. The protection member is configured to protect the first electrode and reduce over-etching of the first electrode. During etching, since the protection member is located at the edge of the first electrode, etching solvent near a periphery of the first electrode first contacts with the protection member, so that the contact between the etching solvent near the periphery of the first electrode and the first electrode can be reduced or avoided, so as to reduce or avoid the over-etching of the first electrode, thereby reducing or avoiding influence on a size of the first electrode.

In an possible implementation, the first conductive line and the first electrode are sequentially disposed on the array layer, and the protection member covers a surface of the first conductive line.

It may be realized that an extension length of the protection member relative to the edge of the first electrode ranges from 1 μm to 4 μm.

It may be realized that an edge of the protection member is a circular arc.

It may be realized that the protection member is integrally formed with the first electrode.

In this way, the first conductive line covered by the protection member cannot absorb too much etching solvent, so that over-etching of the first electrode can be reduced or avoided.

In a possible implementation, an orthogonal projection of the first electrode on the array layer partially overlaps with the orthogonal projection of the first conductive line on the array layer.

In this way, connection stability between the first electrode and the first conductive line can be improved.

In a possible implementation, one first conductive line is electrically connected with a plurality of first electrodes.

It may be realized that the first electrode includes a first transparent electrode layer, a metal electrode layer and a second transparent electrode layer which are sequentially stacked.

It may be realized that the first conductive line is a transparent conductive line.

It may be realized that the first conductive line has a shape of curve.

In a possible implementation, an end of the first conductive line close to the first electrode is provided with a conductive part located between the first electrode and the array layer, and an orthogonal projection of the conductive part on the array layer is located within an orthogonal projection of the first electrode on the array layer.

It may be realized that the orthogonal projection of the conductive part on the array layer is circular or strip-shaped, and the orthogonal projection of the first electrode on the array layer is circular.

It may be realized that a spacing is disposed between an edge of the orthogonal projection of the first electrode on the array layer and an edge of the orthogonal projection of the conductive part on the array layer, and the spacing ranges from 1 μm to 5 μm.

In this way, the conductive part can reduce contact resistance between the first conductive line and the first electrode.

In a possible implementation, the array substrate further includes a pixel definition layer disposed on the array layer and part of the first electrode, the pixel definition layer has a pixel opening, and an orthogonal projection of an end of the pixel opening close to the array layer on the array layer is located between an edge of the orthogonal projection of the first electrode on the array layer and an edge of the orthogonal projection of the conductive part on the array layer.

In a possible implementation, at least two first electrodes form a first electrode unit, a plurality of first electrodes in the first electrode unit are electrically connected with each other via the first conductive line, and the first electrode unit is electrically connected with the array layer via the first conductive line.

A second aspect of the embodiments of the present application provides a display panel including the array substrate in the first aspect.

The display panel provided in the embodiment of the present application includes an array substrate, which includes an array layer, a first conductive line and a first electrode. The first conductive line and the first electrode are disposed on the array layer, and the first electrode is electrically connected with the array layer via the first conductive line, so that the array layer transmits signals to the first electrode via the first conductive line. A protection member is disposed at an edge of the first electrode, and an orthogonal projection of the protection member on the array layer at least partially overlaps with an orthogonal projection of the first conductive line on the array layer. The protection member is configured to protect the first electrode and reduce over-etching of the first electrode. During etching, since the protection member is located at the edge of the first electrode, etching solvent near a periphery of the first electrode first contacts with the protection member, so that the contact between the etching solvent near the periphery of the first electrode and the first electrode can be reduced or avoided, so as to reduce or avoid the over-etching of the first electrode, thereby reducing or avoiding influence on a size of the first electrode.

In a possible implementation, the display panel includes a plurality of light-emitting structures disposed on the array layer of the array substrate, and a same first conductive line of the array substrate is connected with at least two light-emitting structures with same luminous color.

In a possible implementation, the display panel includes a light-transmitting region, a display region and a transition region located between the light-transmitting region and the display region, and the array layer located in the transition region includes a plurality of pixel driving circuits.

One of the pixel driving circuits located in the transition region is electrically connected with a plurality of light-emitting structures located in the light-transmitting region via the first conductive line.

It may be realized that the array layer is provided with a second conductive line located in the light-transmitting region and the transition region and being light-transmissible, and the second conductive line is electrically connected with the first conductive line, and one of the pixel driving circuits located in the transition region is electrically connected with a plurality of the light-emitting structures located in the light-transmitting region via the first conductive line and the second conductive line.

In this way, the influence of the pixel driving circuit on the light transmittance of the light-transmitting region can be avoided.

The configuration of the present application, as well as other inventive purposes and beneficial effects thereof, will be more apparent and easily understood by describing the embodiments with reference to the drawings.

### BRIEF DESCRIPTION OF DRAWINGS

In order to more clearly illustrate technical solutions in embodiments of the present application or the prior art, drawings that need to be used in the description of the embodiments or the prior art will be briefly introduced below. Obviously, the drawings in the following description are some embodiments of the present application, and for those of ordinary skill in the art, other drawings may also be obtained according to these drawings without creative work.

FIG. 1 is a partial cross-sectional view of an array substrate provided in an embodiment of the present application.

FIG. 2 is another partial cross-sectional view of an array substrate provided in an embodiment of the present application.

FIG. 3 is a structural schematic diagram of a light-emitting structure and an array layer provided in an embodiment of the present application.

FIG. 4 is a top view of a first electrode in a light-transmitting region provided in an embodiment of the present application.

FIG. 5 is a structural schematic diagram of a first conductive line provided in an embodiment of the present application.

FIG. 6 is a top view of a first conductive line and a conductive part in a light-transmitting region provided in an embodiment of the present application.

FIG. 7 is a structural schematic diagram of a first conductive line and a first electrode in a light-transmitting region provided in an embodiment of the present application.

FIG. 8 is a structural schematic view of a first electrode covering a surface of a first conductive line provided in an embodiment of the present application.

### DETAILED DESCRIPTION

In the related art, a display panel includes an array substrate including an array layer and a plurality of anodes located on the array layer. The display panel includes a light-transmitting region, a side of the anode in the light-transmitting region facing the array layer is provided with a conductive element, and the array layer may be electrically connected to and transmit signals to the anode through the conductive element.

Before preparing the anode, a conductive element is firstly formed on the array layer, and then an anode material layer is formed on a side of the conductive element facing away from the array layer, and the anode material layer is etched by a wet method (for example, etching with an acidic solvent) to form a plurality of anodes distributed at intervals. The conductive element is a sheet structure, and an orthogonal projection of the anode on the array layer is located in an orthogonal projection of the conductive element on the array layer, and a size of the conductive element is larger than that of the anode, and an exposed area of the conductive part near the periphery of the anode is larger.

However, in the wet etching process of the anode, the acidic etching solvent is formed by polar molecules and the conductive element is also formed by polar molecules, so the polar molecules are attracted to each other. Because the orthogonal projection of the anode on the array layer is located in the orthogonal projection of the conductive element on the array layer, the size of the conductive element is larger, and the exposed area of the conductive part near the periphery of the anode is larger. More etching solvent is easily adsorbed on the conductive element so that the etching solvent concentration near the periphery of the anode is higher, which is easy to over-etch the anode, leads to the small size of the final anode and reduced hole-transport ability of the light-emitting structure, and affects the brightness of the light-emitting structure, thereby affecting the displaying effect of the display panel. In addition, if the anode is over-etched and the size is small, an edge of the anode cannot be covered by a pixel definition layer. When the anode adopts a composite layer of ITO/Ag/ITO (indium tin oxide/silver/indium tin oxide), Ag overflows in the subsequent high-temperature process, resulting in that a short circuit occurs between the anode and a cathode, and dark spots occur on the display panel.

Based on the above problems, embodiments of the present application provide an array substrate and a display panel, the array substrate includes an array layer, and a first conductive line and a first electrode are disposed on the array layer, and the first electrode is electrically connected with the array layer via the first conductive line, so that the array layer transmits signals to the first electrode via the first conductive line. A protection member is disposed at an edge of the first electrode, and an orthogonal projection of the protection member on the array layer at least partially overlaps with an orthogonal projection of the first conductive line on the array layer. The protection member is used to protect the first electrode and reduce over-etching of the first electrode. During etching, since the protection member is located at the edge of the first electrode, etching solvent near a periphery of the first electrode first contacts with the protection member, so that the contact between the etching solvent near the periphery of the first electrode and the first electrode can be reduced or avoided, so as to reduce or avoid the over-etching of the first electrode, thereby reducing or avoiding its influence on a size of the first electrode.

In order to make the purposes, technical solutions and advantages of the embodiments of the present application clearer, the technical solutions in the embodiments of the present application will be described clearly and completely below in conjunction with the drawings of the embodiments of the present application. Obviously, the described embodiments are part of embodiments of the present application, but not all embodiments. Based on the embodiments in the present application, all other embodiments obtained by those of ordinary skill in the art without creative work fall within the protection scope of the present application.

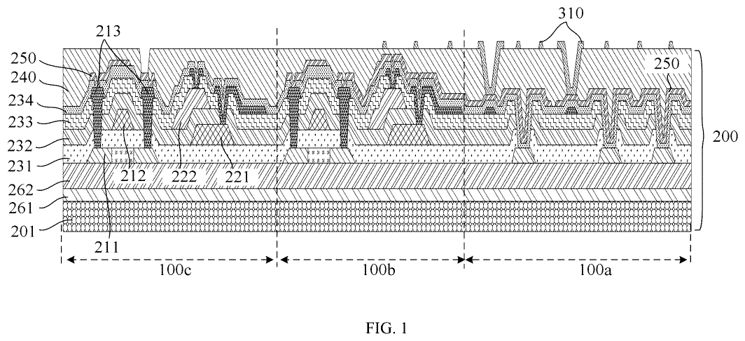

A display device provided in the embodiment of the present application will be described below with reference to FIG. 1 to FIG. 8.

The embodiment of the present application provides a display device, which includes a display panel. The display device may be a mobile or fixed terminal with a display panel, such as electronic paper, mobile phone, tablet computer, television, display, notebook computer, digital photo frame, super personal computer, navigator, etc.

The display panel may be an organic light-emitting diode (Organic Light-Emitting Diode, OLED for short) display panel, a micro light-emitting diode (Micro Light-Emitting Diode, Micro LED or μLED for short) display panel, or a liquid crystal display (Liquid Crystal Display, LCD for short) display panel.

The display panel provided in the embodiment of the present application will be described below.

This embodiment provides a display panel, which may be applied to a display device.

The display panel may include a light-exiting surface and a backlight surface which are oppositely arranged. The light-exiting surface is configured to display a picture, and the backlight surface is an opposite surface to the light-emitting surface in a thickness direction of the display panel.

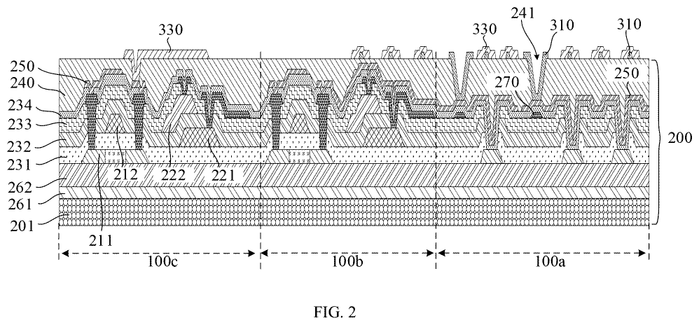

In this embodiment, as shown in FIG. 1-FIG. 2, the display panel may include a light-transmitting region 100a, and an under-screen functional device may be disposed on a side of the backlight surface of the display panel in the light-transmitting region 100a, and the under-screen functional device may include any one or more of a camera, a fingerprint reader, an iris recognizer and a distance sensor.

The embodiment of the present application is described by taking the under-screen functional device as a camera.

A camera is arranged on the side of the backlight surface of the display panel in the light-transmitting region 100a. On the one hand, the display panel in the light-transmitting region 100a can normally display a picture to ensure that the display panel has a high screen-to-body ratio; on the other hand, the light-transmitting region 100a has good light transmission to allow light to reach the camera.

In some examples, the display panel may further include a transition region 100b, which is adjacent to the light-transmitting region 100a and may normally display a picture. The light transmittance of the display panel in the transition region 100b is smaller than that of the display panel in the light-transmitting region 100a. For example, the transition region 100b may be annularly disposed outside the light-transmitting region 100a.

In other examples, the display panel may further include a display region 100c, which may normally display a picture. For example, regions except the light-transmitting region 100a and the transition region 100b are the display region 100c. The light-transmitting region 100a, the transition region 100b and the display region 100c may be arranged sequentially adjacent to each other, that is, the transition region 100b may be located between the light-transmitting region 100a and the display region 100c. Exemplarily, the display region 100c may be annularly disposed outside the transition region 100b. The light transmittance of the display panel in the display region 100c may be less than or equal to that of the display panel in the transition region 100b.

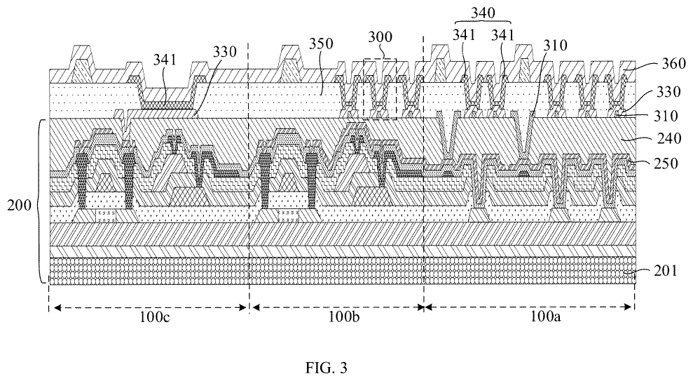

As shown in FIG. 3, the display panel includes an array substrate including an array layer 200, and a light-emitting structure 300 is disposed on the array layer 200. The array layer 200 is provided with a plurality of pixel driving circuits which may be arranged in an array, and the plurality of pixel driving circuits are electrically connected with the light-emitting structure 300, and are used for providing driving current for the light-emitting structure 300.

The array substrate provided in the embodiment of the present application will be described below.

As shown in FIG. 3, the array substrate may include an array layer 200, including a substrate 201 and pixel driving circuits located on the substrate 201; and the pixel driving circuits are located between the light-emitting structure 300 and the substrate 201. The substrate 201 may provide support for the remaining structural layers that are subsequently disposed.

The substrate 201 may be a rigid substrate, for example, a material of the substrate 201 may be glass. In other examples, the substrate 201 may be a flexible substrate, and the material of the substrate 201 may include at least one of polyimide (Polyimide, PI for short), polyethylene terephthalate, polyethylene naphthalate, polycarbonate, polyarylate and polyethersulfone.

It may be understood that, in order to avoid the influence of the pixel driving circuit on the light transmittance of the display panel in the light-transmitting region 100a, the pixel driving circuit may be not disposed in the display panel in the light-transmitting region 100a (the light transmittance of the pixel driving circuit is poor), but disposed in the transition region 100b, so that the pixel driving circuit located in the transition region 100b drives the light-emitting structure 300 in the light-transmitting region 100a to emit light. In addition, the pixel driving circuit in the transition region 100b may also drive the light-emitting structure 300 in the transition region 100b to emit light.

The pixel driving circuit will be described in detail below.

The pixel driving circuit includes a thin film transistor (TFT, Thin Film Transistor) and a capacitor structure, and the thin film transistor may be a low temperature poly-silicon (LTPS, Low Temperature Poly-silicon) thin film transistor or a metal oxide thin film transistor, etc.

Specifically, as shown in FIG. 1, the thin film transistor includes an active layer 211, a gate electrode layer 212 located on a side of the active layer 211 away from the substrate 201 and a source-drain routing layer 213 on a side of the gate electrode layer 212 away from the substrate 201. The capacitor structure includes a first capacitor electrode 221 and a second capacitor electrode 222 which are stacked. The first capacitor electrode 221 and the gate electrode layer 212 are disposed in the same layer and insulated from each other, and the second capacitor electrode 222 is located at a side of the first capacitor electrode 221 away from the substrate 201.

A buffer layer is disposed between the substrate 201 and the active layer 211. The buffer layer may include a first buffer layer 261 and a second buffer layer 262 which are stacked, and the first buffer layer 261 is located on a side of the second buffer layer 262 close to the substrate 201.

A first insulating layer 231 is disposed between the active layer 211 and the gate electrode layer 212; a second insulating layer 232 is disposed between the gate electrode layer 212 and the second capacitor electrode 222; a third insulating layer 233 is disposed between the second capacitor electrode 222 and the source-drain routing layer 213; and a fourth insulating layer 234 is arranged on a side of the source-drain routing layer 213 away from the substrate 201.

A planarization layer 240 is disposed at a side of the fourth insulating layer 234 away from the substrate 201, and provides a good planar support for the subsequent formation of the light-emitting structure 300. A material of the planarization layer 240 may be an inorganic material such as silicon oxide, silicon nitride, etc., or an organic material such as polyethylene (PE), polypropylene, polystyrene, polyethylene terephthalate, polyethylene naphthalate or polyimide, etc.

The gate electrode layer 212, the source-drain routing layer 213, the first capacitor electrode 221 and the second capacitor electrode 222 may adopt a metal such as silver, copper, aluminum and molybdenum or an alloy, or a multilayer structure formed of metal and transparent conductive oxide.

The first buffer layer 261, the second buffer layer 262, the first insulating layer 231, the second insulating layer 232, the third insulating layer 233, and the fourth insulating layer 234 may contain silicon nitride, silicon oxynitride, silicon oxide, or various new organic insulating materials, or metal oxides with high dielectric constant such as aluminum oxide, tantalum oxide, etc.

In this embodiment, as shown in FIG. 3, the array substrate further includes a first electrode 330 and a first conductive line 310, which are located on the array layer 200, and the first electrode 330 is electrically connected with the array layer 200 via the first conductive line 310. Both the first electrodes 330 and the first conductive lines 310 may be multiple. The first electrode 330, the light-emitting layer 340 and a second electrode 360 which are stacked may be configured to form the light-emitting structure 300, and there may be more light-emitting structures 300. The first conductive line 310 is electrically connected with the first electrode 330, thereby electrically connecting with the light-emitting structure 300.

The array substrate further includes a pixel definition layer 350 located at a side of the first electrode 330 away from the substrate 201. As shown in FIG. 2 and FIG. 3, the light-emitting structure 300 includes the second electrode 360 located on the side of the first electrode 330 away from the substrate 201. The light-emitting structure 300 further includes a light-emitting layer 340 located between the first electrode 330 and the second electrode 360. In this embodiment, the first electrode 330 may be an anode, and the second electrode 360 may be a cathode.

The light-emitting layer 340 may include a plurality of pixels 341, which may be arranged in an array and may include at least two colors. For example, the plurality of pixels 341 may include, but are not limited to, red pixels, green pixels and blue pixels. In other examples, the plurality of pixels 341 may also include white pixels. The pixel definition layer 350 is located between two adjacent pixels 341, and the pixel definition layer 350 may be disposed around the periphery of the pixels 341. The pixels 341 are disposed in one-to-one correspondence with the light-emitting structures 300. The first electrodes 330 are disposed in one-to-one correspondence with the pixels 341. The first electrodes 330 in the light-transmitting region 100a, in the transition region 100b and in the display region 100c may be the same or different in terms of material, shape, size and other parameters.

Specifically, the first electrode 330 may have a single-layer structure or a multi-layer structure. Taking a multi-layer structure as an example, the first electrode 330 may include a first transparent electrode layer, a metal electrode layer and a second transparent electrode layer which are sequentially stacked, and the first transparent electrode layer is located at a side of the metal electrode layer away from the substrate 201. Alternatively, the first electrode 330 includes a metal electrode layer and a first transparent electrode layer located at a side of the metal electrode layer away from the substrate 201. Materials of the first transparent electrode layer and the second transparent electrode layer include indium tin oxide (ITO) or indium zinc oxide (IZO), and a material of the metal electrode layer includes magnesium (Mg), silver (Ag) or aluminum (Al), etc. For example, the first electrode 330 may have a multilayer structure of ITO layer/silver layer/ITO layer. The metal electrode layer can reflect light, so that light generated by the pixels 341 can be reflected and emitted out of the display panel to improve the brightness of the display panel in the light-transmitting region 100a.

The first electrode 330 in the embodiment of the present application is illustrated by taking ITO layer/silver layer/ITO layer as an example.

Silver in the first electrode 330 of the embodiment of the present application has a lower resistivity and an excellent conductivity, which can greatly reduce the overall energy consumption of the display panel.

The display panel in the light-transmitting region 100a will be described in detail below.

In this embodiment, as shown in FIG. 3, a first conductive line 310 is disposed on the array layer 200 located in the light-transmitting region 100a, and the first conductive line 310 is configured to electrically connect the light-emitting structure 300 in the light-transmitting region 100a and the pixel driving circuit in the transition region 100b. The first conductive line 310 is made of a conductive material with good light transmittance instead of a metal material, which can avoid the influence of the first conductive line 310 on the light transmittance of the display panel in the light transmittance area 100a. The first conductive line 310 and the first electrode 330 are both located on a side of the planarization layer 240 away from the substrate 201. In an implementation, a material of the first conductive line 310 contains ITO. In some embodiments of the present application, in a direction from the array layer 200 to the first electrode 330, an area of a cross-section of the first electrode 330 parallel to the array layer 200 gradually decreases, that is, a sidewall surface of the first electrode 330 is an inclined surface. This structure helps to reduce the over-etching of the first electrode 330. The plurality of first electrodes 330 are electrically connected with the array layer 200 via the first conductive line 310. Specifically, the first electrodes 330 located in the light-transmitting region 100a may be electrically connected with the pixel driving circuits located in the transition region 100b via the first conductive line 310. One pixel driving circuit may be electrically connected to at least two first electrodes 330. And a plurality of pixels 341 corresponding to at least two first electrodes 330 connected to the same pixel driving circuit may be pixels 341 of the same color. At least two first electrodes 330 may form a first electrode unit, and the plurality of first electrodes 330 in the first electrode unit are electrically connected to each other via the first conductive line 310. In the first electrode unit, the plurality of first electrodes 330 may be electrically connected to each other through the same first conductive line 310, and of course, they may also be electrically connected to each other through a plurality of first conductive lines 310.

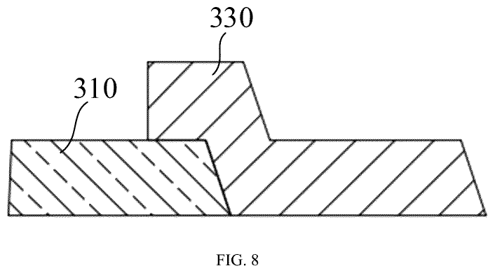

As shown in FIG. 7, the first electrode unit includes four adjacent first electrodes 330, which are electrically connected to each other via the first conductive line 310; and the first electrode unit is electrically connected with the array layer 200 via the first conductive lines 310. The colors of the multiple pixels 341 corresponding to the plurality of first electrodes 330 in the same first electrode unit may be the same or different. Continuing with reference to FIG. 7, the first electrode unit may include four first electrodes 330 that are not adjacent to each other, and the four non-adjacent first electrodes 330 are electrically connected to each other via the first conductive line 310 to form a ring shape, and are electrically connected to the array layer 200 via the first conductive lines 310.

In this embodiment, as shown in FIG. 3, a second conductive line 250 is disposed in the array layer 200 located in the light-transmitting region 100a; and the second conductive line 250 is configured to electrically connect the pixel driving circuit located in the transition region 100b and the first conductive line 310 located in the light-transmitting region 100a. The second conductive line 250 is light-transmissible, thereby preventing the second conductive line 250 from affecting the light transmittance of the display panel in the light-transmitting region 100a.

Specifically, the second conductive line 250 may be located on a side of the planarization layer 240 close to the substrate 201, and may be located between the planarization layer 240 and the fourth insulating layer 234. At least part of the second conductive lines 250 extends from the light-transmitting region 100a to the transition region 100b, and one pixel driving circuit located in the transition region 100b is electrically connected to the plurality of first electrodes 330 (i.e., one first electrode unit) located in the light-transmitting region 100a via the first conductive line 310 and the second conductive line 250, so that the pixel driving circuit located in the transition region 100a transmits signals to a plurality of light-emitting structures 300 located in the light-transmitting region 100a.

As shown in FIG. 2, a via hole 241 may be disposed in the planarization layer 240. The via hole 241 penetrates through the planarization layer 240 in the thickness direction of the display panel, and the first conductive line 310 and the second conductive line 250 are electrically connected to each other through the via hole 241.

In some embodiments, a reflective layer 270 may be disposed in the light-transmitting region 100a. The reflective layer 270 is located on a side of the second conductive line 250 facing the substrate 201. For example, the reflective layer 270 may be disposed in the same layer and contain same material as any one of the gate electrode layer 212, the source-drain routing layer 213, the first capacitor electrode 221 and the second capacitor electrode 222, thereby simplifying the preparation process. An orthogonal projection of the via hole 241 on the substrate 201 is located in an orthogonal projection of the reflective layer 270 on the substrate 201.

In a process of forming the via hole 241, photolithography technology may be adopted. The exposed photoresist is removed during development, thereby exposing a region for the via hole 241 of the planarization layer 240; and the region where the via hole 241 is located is etched to form the via hole 241. There is a pixel driving circuit in the transition region 100b, which includes more reflective metal routings, and the via hole 241 may also be disposed in the planarization layer 240 of the transition region 100b for the electrical connection of the pixel driving circuit in the transition region 100b and the first electrode 330 in the transition region 100b. That is, the via holes 241 of the light-transmitting region 100a and of the transition region 100a may be formed in the planarization layer 240 at the same time. The reflective layer 270 of the light-transmitting region 100a and the pixel driving circuit of the transition region 100b may both reflect the exposed light in the exposure process, so that the consistency of the exposure of the transition region 100b and the light-transmitting region 100a may be improved.

It may be understood that, in the transition region 100b and the display region 100c, a second conductive line 250 may also be disposed. The second conductive line 250 is configured to electrically connect the first electrode 330 and the pixel driving circuit in this region, so that it is not necessary to separately prepare a routing for electrically connecting the first electrode 330 and the pixel driving circuit in this region, and the preparation process may be simplified.

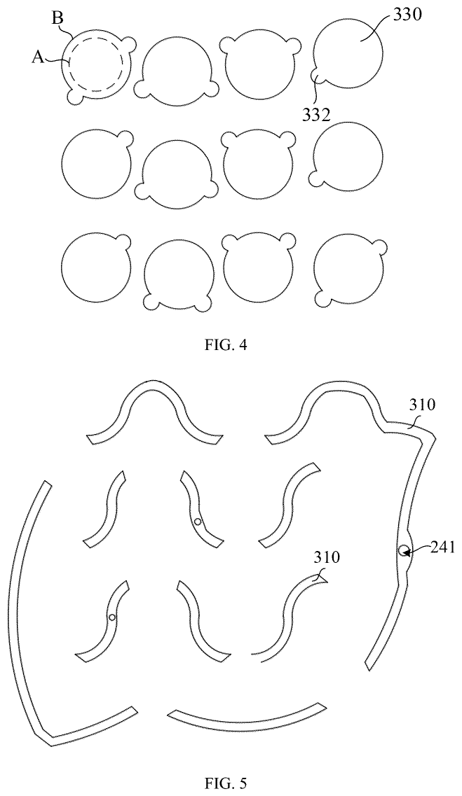

In this embodiment, an orthogonal projection of part of the first electrodes 330 on the array layer 200 overlaps with an orthogonal projection of part of the first conductive lines 310 on the array layer 200, and the first electrodes 330 and the first conductive lines 310 may be electrically connected to each other through the overlapping part. Referring to FIG. 5, the first conductive line 310 is in a linear shape, and the orthogonal projections of the first conductive lines 310 on the array layer 200 partially overlaps with the orthogonal projections of the first electrodes 330 on the array layer 200. A size of the first conductive line 310 is smaller, which reduces an area of the first conductive line 310 exposed near the periphery of the first electrode 330. A contact area between the first conductive lines 310 near the periphery of the first electrode 330 and the etching solution is smaller, which can reduce the adsorption degree of the etching solvent by the first conductive lines 310 near the periphery of the first electrodes 330. That is, a concentration of the etching solvent near the first electrodes 330 is reduced, thereby alleviating the over-etching phenomenon of the first electrodes 330 and improving the display effect of the display panel.

A connection manner of the first electrode 330 and the first conductive line 310 in the embodiment of the present application will be described below.

The first conductive line 310 includes a first surface and a second surface which are disposed oppositely and spaced in a thickness direction, and a sidewall surface connecting the first surface and the second surface. The first surface faces toward the array layer 200, and the second surface is disposed oppositely to the array layer 200, and a surface of the first conductive line 310 at its side facing away from the array layer 200 is the second surface.

As shown in FIG. 8, the first electrode 330 covers a part of the sidewall surface of the first conductive line 310 and a part of the surface at a side of the first conductive line 310 facing away from the array layer 200 (that is, the second surface). That is, an end of the first conductive line 310 close to the first electrode 330 extends to be located between the first electrode 330 and the planarization layer 240, and a part of the first conductive lines 310 is located between the first electrode 330 and the array layer 200, so that there is high connection stability between the first electrode 330 and the first conductive line 310.

As shown in FIG. 3, at least a part of the first electrode 330 is located between the pixel definition layer 350 and the planarization layer 240. The pixel definition layer 350 is located at a side of the array layer 200 and a part of the first electrode 330 facing away from the substrate 201. The pixel definition layer 350 has a pixel opening therein and the pixel 341 is located in the pixel opening. The pixel definition layer 350 covers an edge of the first electrode 330, and an orthogonal projection of an end of the pixel opening close to the array layer 200 on a plane where the first electrode 330 is disposed is located in the first electrode 330. With this arrangement, the pixel definition layer 350 can prevent the edge of the first electrode 330 from being exposed outside the pixel definition layer 350, so that Ag in the first electrode 330 can be prevented from overflowing in the subsequent high-temperature process, thereby reducing the possibility of dark spots appearing on the display panel.

Specifically, the orthogonal projection of the pixel definition layer 350 on the array layer 200 covers an edge of the orthogonal projection of the first electrode 330 on the array layer 200. In FIG. 4, an inner edge A shows the pixel opening, an outer edge B shows the edge of the first electrode 330, and a region between the inner edge A and the outer edge B shows a region where the first electrode 330 is covered by the pixel definition layer 350. A distance between the inner edge A and the outer edge B may range from 1 μm to 4 μm. Specifically, the distance may range from 1.5 μm to 3.5 μm. For example, the distance may be 1 μm, 2 μm, 2.5 μm, 2.7 μm, 3 μm, 3.4 μm, 4 μm or any value of 1 μm to 4 μm. In this way, it can be avoided that the pixel definition layer 350 covers the first electrode 330 too little, resulting in that the edge of the first electrode 330 tends to be exposed to the outside of the pixel definition layer 350, which causes the display panel to be prone to dark spots. It can also be avoided that the pixel definition layer 350 covers the first electrode 330 too much, resulting in that the first electrode 330 is too large, which has a great influence on the light transmittance of the light-transmitting region 100a.

In some embodiments, as shown in FIG. 4 and FIG. 7, the edge of the first electrode 330 is provided with a protection member 332. The protection member 332 is connected to the edge of the first electrode 330. For example, the protective member 332 and the first electrode 330 may be integrally formed, so that the protective member 332 and the first electrode 330 may be prepared at the same time, and the connection stability between the protective member 332 and the first electrode 330 is high and the preparation difficulty is low. Of course, the protective member 332 and the first electrode 330 may also be two separate structural layers.

The protection member 332 may be disposed at a part of the edge of the first electrode 330, or the protection member 332 may be disposed at the whole edge of the first electrode 330. During etching, because the protective member 332 is located at the edge of the first electrode 330, the etching solvent near the periphery of the first electrode 330 contacts with the protective member 332 first, so that the contact between the etching solvent near the periphery of the first electrode 330 and the first electrode 330 may be reduced or avoided, so as to reduce or avoid the over-etching of the first electrode 330, thereby reducing or avoiding the influence of over-etching on the size of the first electrode 330.

An orthogonal projection of the protection member 332 on the array layer 200 partially or completely overlaps with the orthogonal projection of the first conductive line 310 on the array layer 200. In some examples, the orthogonal projection of the protection member 332 on the array layer 200 completely overlaps with the orthogonal projection of the first conductive line 310 on the array layer 200, so that the over-etching of the first electrode 330 caused by the etching solvent adsorbed by the first conductive line 310 can be completely avoided. In other examples, the orthogonal projection of the protective member 332 on the array layer 200 partially overlaps with the orthogonal projection of the first conductive line 310 on the array layer 200, and the area of the protective member 332 is small, thus having a small impact on the light transmittance of the display panel. For example, the protective member 332 covers a portion of the surface at an end of the first conductive line 310 close to the first electrode 330. The protective member 332 covers a portion of the sidewall surface of the first conductive line 310 and a portion of the surface at a side of the first conductive line 310 facing away from the array layer 200. During etching, the end of the first conductive line 310 near the first electrode 330 may adsorb etching solvent, thus affecting the region of the first electrode 330 close to the first conductive line 310. By covering the end of the first conductive line 310 close to the first electrode 330 with the protection member 332, it can be avoided that the end of the first conductive line 310 near the first electrode 330 is in contact with the etching solvent, thereby preventing the first conductive line 310 at this end from absorbing too much etching solvent, protecting the first electrode 330 during etching, avoiding the problem that the first electrode 330 is over-etched, and thus avoiding affecting the size of the first electrode 330.

Through a large number of anode etching experiments, the inventors found that an extension length of the protection member 332 relative to the edge of the first electrode 330 may range from 1 μm to 4 μm. Specifically, the extension length of the protection member 332 relative to the edge of the first electrode 330 may range from 1.5 μm to 3.5 μm. For example, the extension length of the protection member 332 may be 1 μm, 1.5 μm, 2 μm, 2.5 μm, 3 μm, 3.5 μm, 4 μm, or any value ranging 1 μm to 4 μm. Therefore, it can be avoided that the extension length of the protection member 332 relative to the edge of the first electrode 330is too short, resulting in a weaker protective effect on the first electrode 330. It can also be avoided that the extension length of the protection member 332 relative to the edge of the first electrode 330 is too large, which has a great influence on the light transmittance of the light-transmitting region 100a. A direction of the extension length of the protective member 332 may be the same as an extension direction of the length of the first conductive line 310.

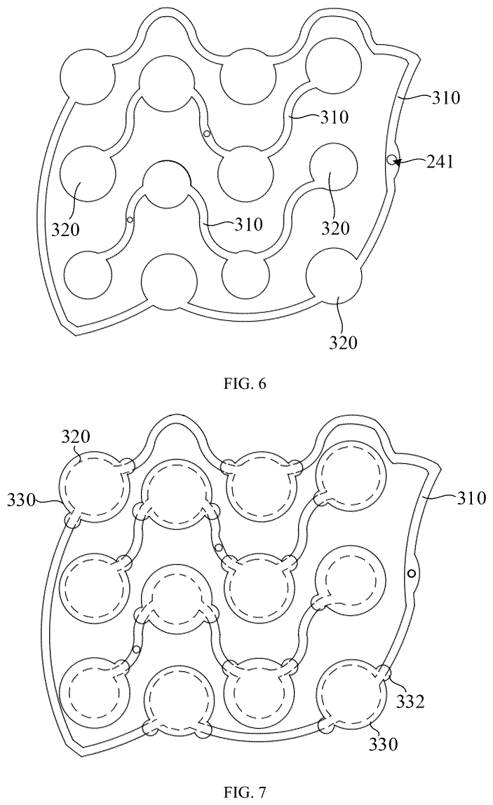

In some embodiments, as shown in FIG. 6 and FIG. 7, an end of the first conductive line 310 near the first electrode 330 is provided with a conductive part 320, which is located between the first electrode 330 and the array layer 200. Specifically, the conductive part 320 is located between the first electrode 330 and the planarization layer 240, and an orthogonal projection of the conductive part 320 on the array layer 200 is located within the orthogonal projection of the first electrode 330 on the array layer 200. The size of the first electrode 330 is larger than that of the conductive part 320, so that the exposure of the conductive part 320 to the outside of the first electrode 330 can be avoided, and the contact of the conductive part 320 with the etching solvent, which affects the etching of the first electrode 330, is avoided. In addition, the conductive part 320 may increase a contact area between the first electrode 330 and the first conductive line 310, thereby reducing the contact resistance.

It may be understood that the end of the first conductive line 310 near the first electrode 330 may be provided with a conductive part 320 to reduce the contact resistance. Of course, the end of the first conductive line 310 near the first electrode 330 may not be provided with the conductive part 320, so that the influence of the conductive part 320 on the film quality of the first electrode 330 can be avoided, and the migration of Ag in the first electrode 330 caused by the degradation of the film quality is reduced, thereby reducing the probability of dark spots on the display panel.

In some embodiments of the present application, two first conductive lines 310 electrically connected with the same first electrode 330 are electrically connected to each other through the conductive part 320, that is, it may regarded as the first electrode 330 is electrically connected with one first conductive line 310. When a plurality of first electrodes 330 is electrically connected to each other via the first conductive line 310, it may be regarded that the plurality of first electrodes 330 is electrically connected to each other through one first conductive line 310.

Shapes of the first electrode 330 and of the conductive part 320 may be the same or different.

When the shapes of the first electrode 330 and of the conductive part 320 are the same, the shape of the first electrode 330 is adapted to that of the conductive part 320. In this way, the first electrode 330 may better cover the conductive part 320 to prevent the conductive part 320 from being exposed outside the first electrode 330. Specifically, there is a spacing between an edge of the orthogonal projection

of the first electrode 330 on the array layer 200 and an edge of the orthogonal projection of the conductive part 320 on the array layer 200. Exemplarily, the spacing may range from 1 μm to 5 μm. Specifically, the spacing may range from 2 μm to 4 μm. For example, the spacing may be 1 μm, 2 μm, 3 μm, 4 μm, 5 μm, or any value of 1 μm to 5 μm. Accordingly, it can be avoided that too small size of the conductive part 320 results in a weak effect on improving the contact resistance between the first electrode 330 and the first conductive line 310. It can also be avoided that too large size of the conductive part 320 results in that the first electrode 330 cannot cover the conductive part 320 well (due to manufacturing errors), thereby causing the conductive part 320 to contact with the etching solvent, and thus affecting the etching of the first electrode 330.

Exemplarily, an orthogonal projection of an end of the pixel opening near the array layer 200 on the array layer 200 is located between the edge of the orthogonal projection of the first electrode 330 on the array layer 200 and the edge of the orthogonal projection of the conductive part 320 on the array layer 200. In this case, the pixel definition layer 350 covers the edge of the first electrode 330, which can prevent the edge of the first electrode 330 from being exposed outside the pixel definition layer 350. In addition, there is a spacing between a patterning the orthogonal projection of the pixel definition layer 350 on the array layer 200 and the edge of the orthogonal projection of the conductive part 320 on the array layer 200, rather than overlapping, which can avoid the influence of the conductive part 320 on the flatness of the pixel definition layer 350. The conductive part 320 has a small area, which has little influence on the film quality of the first electrode 330.

In some embodiments, a surface of the first electrode 330 at its side facing away from the array layer 200 may be flat. For example, a side of the planarization layer 240 facing away from the array layer 200 may be provided with a groove, in which the first conductive line 310 may be disposed, and a surface of the first conductive line 310 at its side facing away from the array layer 200 is flush with a surface of the planarization layer 240 at its side facing away from the array layer 200. In this way, the effect of the first conductive line 310 on the flatness of the surface of the first electrode 330 at its side facing away from the array layer 200 is avoidable, thereby avoiding the display effect of the display panel.

It should be noted that, when light passes through the display panel of the light-transmitting region 100a and reaches the camera, it may be diffracted upon passing through the structural layers such as the first conductive line 310 and the first electrode 330. “Diffraction” refers to a phenomenon that when light passes through obstacles such as a slit, a small hole or a disk, it will undergo varying degrees of bending-spreading propagation, thus deviating from the original straight line propagation. In the process of diffraction, light interferes with each other to form light and dark diffraction fringes, which may affect the function of the camera. Diffraction fringes are influenced by a size of the obstacle, such as a width of the slit and a size of the small hole, and positions of diffraction fringes produced at the same width positions are consistent, thus obvious diffraction effect may appear.

A shape of the first conductive lines 310 may be a curve, so that gap widths of different positions between adjacent first conductive lines 310 are different, positions of diffraction fringes generated at different gap widths are different, and the diffraction effects at different positions cancel out each other, so that the diffraction effects may be effectively weakened to ensure the normal operation of the camera. Exemplarily, the first conductive line 310 is shaped as a circular arc which is more regular and less difficult to prepare.

In addition, the orthogonal projection of the first electrode 330 on the array layer 200 may be in a circular shape, an elliptical shape or other irregular shapes, so as to ensure that diffraction fringes with different positions and directions may be generated at different width positions of the first electrode 330 when light passes through the first electrode 330, and the diffraction fringes with different positions and directions offset each other, thereby weakening the diffraction effect.

In a direction from the array layer 200 to the first electrode 330, the area of the cross section of the first electrode 330 parallel to the array layer 200 is gradually decreased and a side surface of the first electrode 330 is an inclined surface, so that an area of the side surface of the first electrode 330 may be increased, which is beneficial to stable connection between the structural layer attached to the side surface of the first electrode 330 and the first electrode 330, and pores are less likely to appear therebetween.

The orthogonal projection of the conductive part 320 on the array layer 200 may also be in a circular shape, an elliptical shape, a strip shape or other irregular shapes.

An edge of the protection member 332 is shaped as a circular arc, so as to ensure that diffraction fringes with different positions and directions may be generated at different positions of the edge of the protection member 332 when light passes through the protection member 332, and the diffraction fringes with different positions and directions offset each other, thus weakening the diffraction effect.

The embodiment of the present application also provides a preparation method of the array substrate, which may be used for preparing the array substrate in the above embodiments.

The preparation method of the array substrate may include the following steps.

First, an array layer is provided.

As shown in FIG. 1, an array layer 200 is provided first, and the array layer 200 including pixel driving circuits.

Then, a plurality of first conductive lines are formed on the array layer.

As shown in FIG. 1, a plurality of first conductive lines 310 are formed on the array layer 200.

Specifically, first, a first conductive layer is deposited on the array layer 200 and is patterned to remove a portion of the first conductive layer, and the remaining portion of the first conductive layer is formed as the first conductive lines 310.

Then, a plurality of first electrodes is formed on the array layer, and a portion of surfaces of the first conductive lines is covered by the first electrodes.

Specifically, a second conductive layer is formed on the first conductive lines 310 and the array layer 200 and is patterned to remove a portion of the second conductive layer, and the remaining portion of the second conductive layer is formed as a first electrode 330.

As shown in FIG. 2, a plurality of first electrodes 330 is formed on the array layer 200, and the first electrode 330 covers a portion of the sidewall surface of the first conductive line 310 and a portion of the surface of the first conductive line 310 facing away from the array layer 200, so that the electrical connection between the first electrode 330 and the first conductive line 310 is realized. The first electrodes 330 are electrically connected to the pixel driving circuits in the array layer 200 via the first conductive lines 310.

The first conductive line 310 is in a linear structure. Compared with a sheet structure in the related art, an area of the first conductive line 310 in the linear structure is smaller, and the orthogonal projection of the first conductive line 310 on the array layer 200 partially overlaps with the orthogonal projection of the first electrode 330 on the array layer 200. The size of the first conductive line 310 is smaller, which reduces the area of the first conductive line 310 exposed near the periphery of the first electrode 330. The contact area between the first conductive line 310 near the periphery of the first electrode 330 and the etching solution is smaller, which can reduce the adsorption degree of the etching solvent by the first conductive line 310 near the periphery of the first electrode 330. That is, the concentration of the etching solvent near the first electrode 330 is reduced, thereby alleviating the over-etching phenomenon of the first electrode 330 and thus improving the displaying effect of the display panel.

It should be noted here that numerical values and numerical ranges involved in the embodiments of the present application are approximations, and there may be a certain range of errors due to the influence of the manufacturing process, which may be considered negligible by those of skill in the art.

Finally, it should be noted that the above embodiments are merely used to describe the technical solutions of the present application, rather than limiting them. Although the present application has been described in detail with reference to the foregoing embodiments, it should be understood by those of ordinary skill in the art that the technical solutions described in the foregoing embodiments may still be modified, or some or all of their technical features may be replaced by equivalents. However, these modifications or replacements do not make the essence of the corresponding technical solutions depart from the scope of the technical solutions of various embodiments of the present application.

What is claimed is:

1. An array substrate, comprising:
an array layer;
a first conductive line disposed on the array layer;
at least one first electrode disposed on the array layer and electrically connected with the array layer via the first conductive line; and
a protection member disposed on an edge of the at least one first electrode, and an orthogonal projection of the protection member on the array layer at least partially overlaps with an orthogonal projection of the first conductive line on the array layer.

2. The array substrate according to claim 1, wherein the first conductive line and the at least one first electrode are sequentially disposed on the array layer, and the protective member covers a surface of the first conductive line.

3. The array substrate according to claim 1, wherein an extension length of the protection member relative to the edge of the at least one first electrode ranges from 1 μm to 4 μm.

4. The array substrate according to claim 1, wherein an edge of the protection member is a circular arc.

5. The array substrate according to claim 1, wherein the protection member is integrally formed with the at least one first electrode.

6. The array substrate according to claim 1, wherein an orthogonal projection of the at least one first electrode on the array layer partially overlaps with the orthogonal projection of the first conductive line on the array layer.

7. The array substrate according to claim 1, wherein the one first conductive line is electrically connected with a plurality of first electrodes.

8. The array substrate according to claim 1, wherein the at least one first electrode comprises a first transparent electrode layer, a metal electrode layer, and a second transparent electrode layer which are sequentially stacked.

9. The array substrate according to claim 1, wherein the first conductive line is a transparent conductive line.

10. The array substrate according to claim 1, wherein the first conductive line has a shape of curve.

11. The array substrate according to claim 1, wherein an end of the first conductive line close to the at least one first electrode is provided with a conductive part located between the at least one first electrode and the array layer, and an orthogonal projection of the conductive part on the array layer is located within an orthogonal projection of the at least one first electrode on the array layer.

12. The array substrate according to claim 11, wherein the orthogonal projection of the conductive part on the array layer is circular or strip-shaped in shape, and the orthogonal projection of the at least one first electrode on the array layer is circular in shape.

13. The array substrate according to claim 11, wherein a spacing is disposed between an edge of the orthogonal projection of the at least one first electrode on the array layer and an edge of the orthogonal projection of the conductive part on the array layer, and the spacing ranges from 1 μm to 5 μm.

14. The array substrate according to claim 11, further comprising a pixel definition layer disposed on the array layer and part of the at least one first electrode, wherein the pixel definition layer has a pixel opening, and an orthogonal projection of an end of the pixel opening close to the array layer on the array layer is located between an edge of the orthogonal projection of the at least one first electrode on the array layer and an edge of the orthogonal projection of the conductive part on the array layer.

15. The array substrate according to claim 1, wherein the at least one first electrode comprises a plurality of first electrodes, at least two first electrodes of the plurality of first electrodes form a first electrode unit, of the at least two first electrodes in the first electrode unit are electrically connected with each other via the first conductive line, and the first electrode unit is electrically connected with the array layer via the first conductive line.

16. The array substrate according to claim 2, wherein the at least one first electrode comprises a plurality of first electrodes, at least two first electrodes of the plurality of first electrodes form a first electrode unit, the at least two first electrodes in the first electrode unit are electrically connected with each other via the first conductive line, and the first electrode unit is electrically connected with the array layer via the first conductive line.

17. A display panel comprising the array substrate according to claim 1.

18. The display panel according to claim 17, further comprising a plurality of light-emitting structures disposed on the array layer of the array substrate, wherein a first conductive line of the array substrate is connected with at least two light-emitting structures emitting light of a same luminous color.

19. The display panel according to claim 18, further comprising a light-transmitting region, a display region and a transition region located between the light-transmitting region and the display region, wherein the array layer located in the transition region comprises a plurality of pixel driving circuits; and
one of the pixel driving circuits located in the transition region is electrically connected with a plurality of light-emitting structures located in the light-transmitting region via the first conductive line.

20. The display panel according to claim 19, wherein the array layer is provided with a translucent second conductive line located in the light-transmitting region and the transition region, the second conductive line is electrically connected with the first conductive line, and one of the pixel driving circuits located in the transition region is electrically connected with the plurality of the light-emitting structures located in the light-transmitting region via the first conductive line and the second conductive line.
